(19) United States
(12) Patent Application Publication
(10) Pub. No.: US 2024/0387181 A1
(43) Pub. Date: Nov. 21, 2024

(54) METHOD FOR MANUFACTURING SEMICONDUCTOR MEMBER

(71) Applicant: SUMITOMO CHEMICAL COMPANY, LIMITED, Tokyo (JP)

(72) Inventor: Hajime FUJIKURA, Hitachi-shi (JP)

(73) Assignee: SUMITOMO CHEMICAL COMPANY, LIMITED, Tokyo (JP)

(21) Appl. No.: 18/629,609

(22) Filed: Apr. 8, 2024

(30) Foreign Application Priority Data
May 16, 2023 (JP) 2023-080631

(51) Int. Cl. H01L 21/306; H01L 21/308; H01L 29/66

(52) U.S. Cl. CPC H01L 21/30604; H01L 21/308; H01L 29/66795

(57) ABSTRACT

There is provided a method for manufacturing a semiconductor member, the method including: preparing a processing target comprising a wafer composed of a conductive semiconductor and a mask disposed on a top surface of the wafer; and photoelectrochemically etching the wafer by immersing the processing target in an etching solution and irradiating light from a top surface side of the wafer, wherein in the photoelectrochemical etching of the wafer, an outer portion of the mask of the wafer is etched to form a protrusion under the mask, and a first side surface and a second side surface are etched until an entire width between the mutually opposing first side surface and second side surface of the protrusion is depleted, to automatically stop the etching of the first side surface and the second side surface.

### TECHNICAL FIELD

The present invention relates to a method for manufacturing a semiconductor member.

### DESCRIPTION OF RELATED ART

A semiconductor member with a structure formed in a semiconductor material is widely used in a semiconductor element and the like. For example, a fin field effect transistor with a fin structure formed as a gate portion is known (for example, see Patent literature 1). For example, a structure used in a semiconductor element is preferably formed in a precise shape because it affects operating characteristics of the device. Patent Literature 1: International Publication No. 2017/047286

### SUMMARY OF THE INVENTION

One object of the present invention is to provide a novel method for manufacturing a semiconductor member used in a semiconductor element and the like.

According to one aspect of the present invention, there is provided a method for manufacturing a semiconductor member, the method including:
preparing a processing target comprising a wafer composed of a conductive semiconductor and a mask disposed on a top surface of the wafer; and
photoelectrochemically etching the wafer by immersing the processing target in an etching solution and irradiating light from a top surface side of the wafer,
wherein in the photoelectrochemical etching of the wafer,
an outer portion of the mask of the wafer is etched to form a protrusion under the mask, and
a first side surface and a second side surface are etched until an entire width between the mutually opposing first side surface and second side surface of the protrusion is depleted, to automatically stop the etching of the first side surface and the second side surface.

A novel method for manufacturing a semiconductor member

used in a semiconductor element and the like is provided.

### BRIEF DESCRIPTION OF THE DRAWINGS

FIGS. 1A and 1B are a cross-sectional view and a top view, respectively, schematically illustrating an FET 100 according to an embodiment of the present invention.

FIG. 2A is a cross-sectional view schematically illustrating a processing target 150 in PEC etching according to an embodiment, and FIG. 2B is a cross-sectional view schematically illustrating a PEC etching apparatus 200 according to an embodiment.

FIGS. 3A to 3C are schematic cross-sectional views illustrating portions of a wafer 10a and a semiconductor member 10 near a mask 160 during PEC etching according to an embodiment.

FIGS. 4A and 4B are a cross-sectional view and a top view, respectively, schematically illustrating an FET 100 according to a first modified example.

FIG. 5 is a top view schematically illustrating the FET 100 according to a second modified example.

FIG. 6A is a table showing a dependence of twice a depletion layer width Wp at each carrier concentration n, on an applied voltage V when the Schottky barrier Φ_{B} is 1 eV. FIG. 6B is a table showing the allowable error of a width W of a gate protrusion 16 when an allowable error of a threshold value is ±50 mV and ±100 m V.

### DETAILED DESCRIPTION OF THE INVENTION

A method for manufacturing a semiconductor member according to an embodiment of the present invention will be described. Here, explanation will be given by citing a field effect transistor (FET), which is a semiconductor element, as an example of the semiconductor member according to an embodiment. The semiconductor member according to the embodiment may include only a semiconductor member, or as in this example, it may include a semiconductor member and other member such as an electrode. Further, the use of the semiconductor member manufactured by the manufacturing method of the embodiment does not have to be limited to FET.

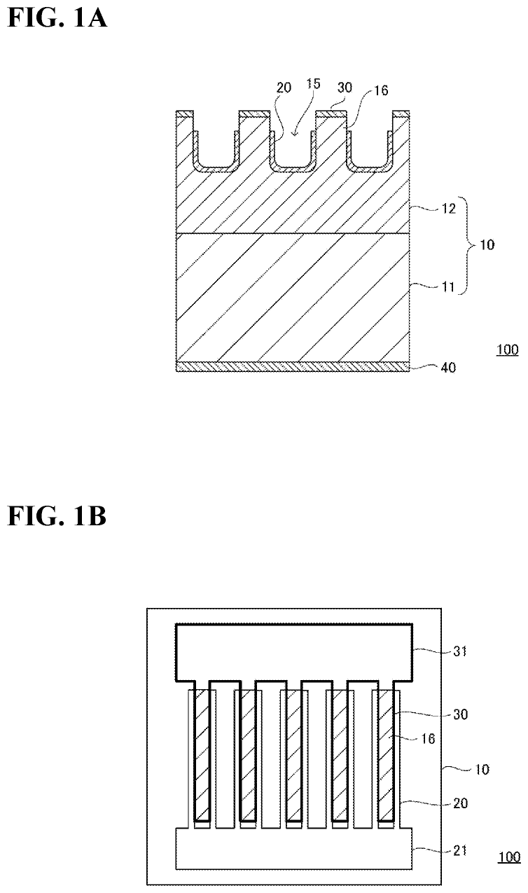

The structure and operation of the FET 100 according to the embodiment will be described for example. FIGS. 1A and 1B are a cross-sectional view and a top view, respectively, schematically illustrating the FET 100 according to an embodiment. The FET 100 includes a semiconductor member 10, a gate electrode 20, a source electrode 30, and a drain electrode 40. The FET 100 may include other member such as an insulating film as necessary.

The semiconductor member 10 is composed of a semiconductor material having conductivity by containing an n-type conductive impurity (hereinafter also simply referred to as an impurity) at a predetermined concentration. As the semiconductor material constituting the semiconductor member 10, a material that can be etched by photoelectrochemical (PEC) etching can be used as appropriate, and for example, gallium nitride (GaN), silicon carbide (SiC), etc., are used. In addition to a wide gap semiconductor such as GaN, a conventional compound semiconductor such as gallium arsenide (GaAs) and indium phosphide (InP) may be used. Here, explanation will be given, using GaN containing an n-type impurity such as silicon (Si) as an example of the semiconductor material constituting the semiconductor member 10.

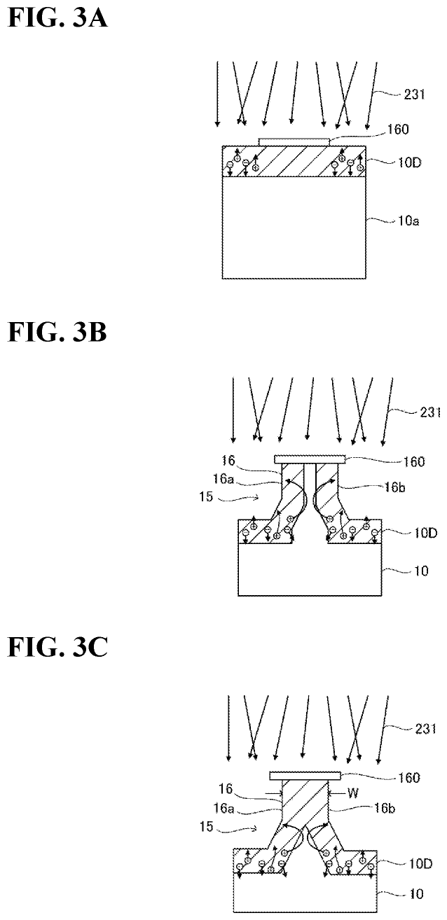

The semiconductor member 10 used in the FET 100 of this example includes a substrate 11 and a layer 12 epitaxially grown on the substrate 11 (hereinafter referred to as a drift layer 12). A protrusion 16 (hereinafter referred to as a gate protrusion 16) is formed on the drift layer 12 by the manufacturing method (processing method) according to the embodiment, specifically, by PEC etching. The gate protrusion 16 has a width W (see FIG. 3C). As will be described in detail later, the width W of the gate protrusion 16 is determined by the carrier concentration of the drift layer 12. In other words, the carrier concentration of the drift layer 12, that is, the impurity concentration added to the drift layer 12, is set so that a predetermined width W can be obtained.

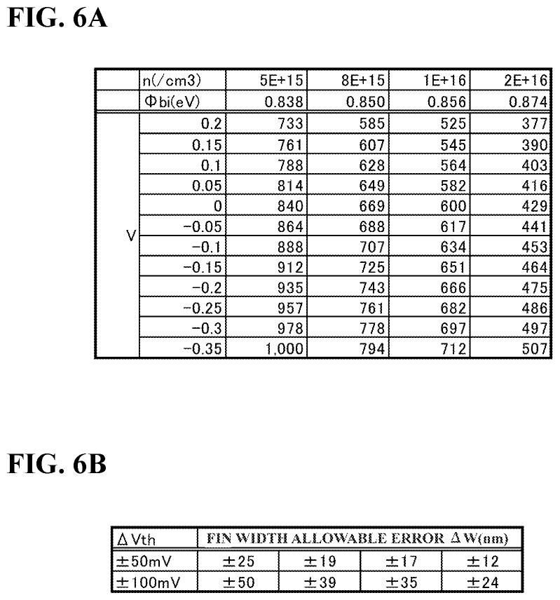

For example, by setting the carrier concentration of the drift layer 12 to about 1×10¹⁶/cm³, the width W of the gate protrusion 16 can be set to 600 nm (see FIG. 6A). By lowering the carrier concentration of the drift layer 12, the width W of the gate protrusion 16 can be widened, and by increasing the carrier concentration of the drift layer 12, the width W of the gate protrusion 16 can be narrowed (see FIG. 6A). The width W of the gate protrusion 16 (more specifically, the width W of the narrowest portion of the gate protrusion 16) is preferably 200 nm or more and 2000 nm or less. The carrier concentration of the drift layer 12 is set so that the width W of the gate protrusion 16 falls within such a range. Depending on the semiconductor material used (because the width of the depletion layer depends on the dielectric constant of the semiconductor material), the relationship between the carrier concentration of the drift layer 12 and the width W of the gate protrusion 16 may be varied to some extent. The precise relationship between the carrier concentration of the drift layer 12 and the width W of the gate protrusion 16 in the used semiconductor material may be determined, for example, by a preliminary experiment, and the carrier concentration of the drift layer 12 may be set based on the determined precise relationship.

The gate protrusion 16 is formed on the top surface of the semiconductor member 10, that is, on the top surface of the drift layer 12, and a recess 15 (hereinafter referred to as a gate recess 15) is formed on the outer side of the gate protrusion 16 (in planer view).

The gate recess 16 functions as a gate portion of the FET 100. In this example, the FET 100 is a FinFET, and as illustrated in FIG. 1B, the gate protrusion 16 (hatched portion upward to the right) has a fin-like (linear) shape.

The height of the gate protrusion 16 (that is, the depth of the gate recess 15) may be set as appropriate, and is, for example, about 1 um. The height of the gate protrusion 16 is the thickness of the gate portion in a current flow direction, and when it is too thin (too low), it is not preferable from a viewpoint of a current control. Therefore, it is preferable that the height of the gate protrusion 16, that is, the depth of PEC etching when forming the gate protrusion 16, is, for example, 500 nm or more.

A gate electrode 20 is disposed on the inner surface of the gate recess 15 and at least on the side surface of the gate protrusion 16. The gate electrode 20 is disposed on one side surface of the gate protrusion 16 and on the other side surface opposite to this side surface so as to sandwich the side portion of the gate protrusion 16 from both sides. The gate electrode 20 is connected to a gate pad 21 disposed on the top surface of the semiconductor member 10, and connected to an external circuit via the gate pad 21.

A gate voltage is applied to the side surface of the gate protrusion 16 by the gate electrode 20. By controlling the gate voltage, the carrier distribution within the gate protrusion 16 is changed to switch the FET 100 between the ON state and the OFF state. As will be described later in detail, since the gate protrusion 16 formed by the manufacturing method of the embodiment is fully depleted, the FET 100 is of a normally-off type. That is, the ON operation of applying a predetermined positive voltage to the gate electrode 20 increases the number of electrons in the gate protrusion 16, and the FET 100 can be set in the ON state.

FIGS. 1A and 1B illustrate a Schottky-type gate electrode structure in which the gate electrode 20 is disposed directly on the side surface of the gate protrusion 16. However, if necessary, a MOS type gate electrode structure may be used in which the gate electrode 20 is disposed on the side surface of the gate protrusion 16 with a gate insulating film interposed therebetween.

A source electrode 30 is disposed on the top surface of the gate protrusion 16 (on one side of the gate protrusion 16 in a vertical direction). The source electrode 30 is connected to a source pad 31 disposed on the top surface of the semiconductor member 10, and connected to an external circuit via the source pad 31. A drain electrode 40 is disposed on the bottom surface of the semiconductor member 10, that is, on the bottom surface of the substrate 11 (on the other side of the gate protrusion 16 in the vertical direction).

By applying a gate voltage to the gate electrode 20 and setting the FET 100 in the ON state while a predetermined voltage is applied between the source electrode 30 and the drain electrode 40, the FET 100 can be operated so that a drain current flows in a thickness direction (vertical direction) of the semiconductor member 10.

A method for manufacturing the FET 100 will be described for example. The gate protrusion 16 is formed on the top surface of a flat semiconductor member 10a (hereinafter referred to as a wafer 10a) on which the gate protrusion 16 has not yet been formed (on the top surface of the drift layer 12). The semiconductor member 10 is obtained by forming the gate protrusion 16 on the wafer 10a. The method for manufacturing the FET 100 according to the embodiment is characterized in that the gate protrusion 16 is formed by PEC etching, as will be described later in detail.

Thereafter, appropriately using a known technique for patterning a metal film, a known technique for patterning an insulating film, etc., the FET 100 is manufactured by forming the gate electrode 20, source electrode 30, drain electrode 40, and other member such as an insulating film on the semiconductor member 10.

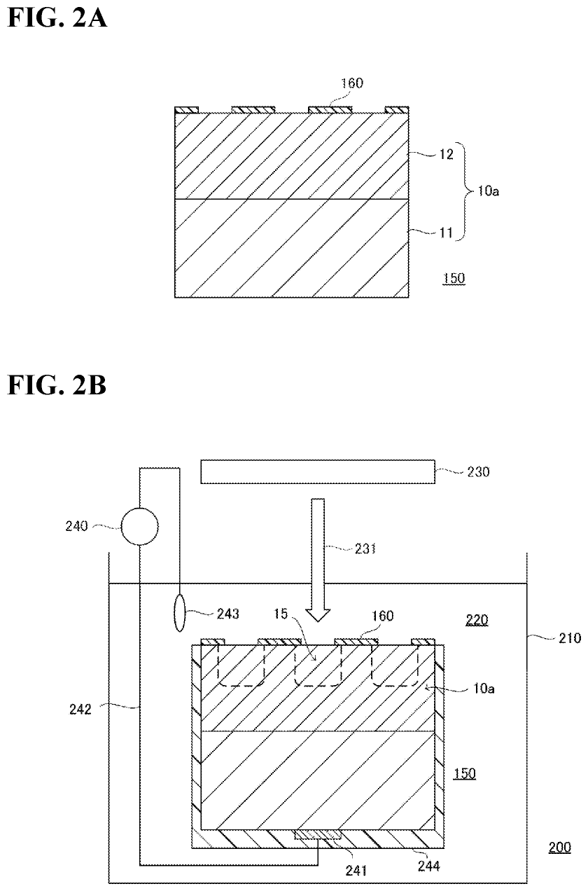

The step of forming the gate protrusion 16 by PEC etching will be described in detail. FIG. 2A is a cross-sectional view schematically illustrating a processing target 150 in PEC etching according to the embodiment. The processing target 150 includes a wafer 10a and a mask 160. The wafer 10a includes the substrate 11 and the drift layer 12, as described above. The mask 160 is disposed on the top surface of the wafer 10a (on the top surface of the drift layer 12) in a region where the gate protrusion 16 is to be formed. As the mask 160, a resist mask, a hard mask, etc., may be used as appropriate. It is preferable that the mask 160 has a light-shielding property that does not transmit light 231 irradiated in PEC etching, which will be described later.

FIG. 2B is a cross-sectional view schematically illustrating the PEC etching apparatus 200 according to the embodiment. An etching solution (electrolyte) 220 is contained in a container 210, and the processing target 150 is immersed in the etching solution 220. A processing target side electrode 241 is disposed on the bottom surface of the wafer 10a (on the bottom surface of the substrate 11), and the processing target 150 is immersed in the etching solution 220 while the object-side electrode 241 and the bottom and side surfaces of the wafer 10a are covered with a coating member 244 such as a resist so as not to be exposed to the etching solution 220 (so as not to make electrical contact with the etching solution 220). Thereby, an opening region of the mask 160 on the top surface of the wafer 10a (on the top surface of the drift layer 12) is selectively exposed to the etching solution 220.

As the etching solution 220, an etching solution capable of PEC etching the semiconductor material constituting the wafer 10a (more specifically, the semiconductor material constituting the drift layer 12), may be used as appropriate (potassium hydroxide aqueous solution, phosphoric acid aqueous solution, etc.). The etching solution 220 may be alkaline or acidic as necessary. As will be described later, the pH of the etching solution 220 is appropriately adjusted according to the width W of the gate protrusion 16, and the etching solution 220 corresponding to a suitable pH is used.

One end of a wiring 242 (covered with insulation) is connected to the processing target side electrode 241. An etching solution side electrode 243 is attached to the other end of the wiring 242, and the etching solution side electrode 243 is immersed in the etching solution 220. A voltage source 240 is disposed in the middle of the wiring 242. The voltage source 240 applies a predetermined etching voltage for performing PEC etching, between the processing target side electrode 241 and the etching solution side electrode 243, that is, between the wafer 10a and the etching solution 220.

With an etching voltage applied between the wafer 10a and the etching solution 220, light 231 for performing PEC etching is irradiated from the light source 230 onto the top surface of the wafer 10a, that is, the top surface of the drift layer 12, which is the surface to be etched. In this way, PEC etching is performed to the wafer 10a.

FIGS. 3A to 3C are schematic cross-sectional views illustrating portions of the wafer 10a and the semiconductor member 10 near the mask 160 during PEC etching according to an embodiment. See FIG. 3A. As the etching voltage, a voltage that is positive on the wafer 10a side and negative on the etching solution 220 side is applied. Light 231 is irradiated, having a wavelength corresponding to a larger energy than the bandgap of the semiconductor material constituting the top surface of the wafer 10a, which is the region to be etched.

A depletion layer 10D (hatched portion upward to the right) is formed on the top surface of the wafer 10a. Due to optical excitation caused by irradiation of the light 231 onto the upper surface of the wafer 10a, pairs of electrons and holes are generated in the surface layer of the top surface. Due to a negative voltage applied to the etching solution 220, the holes are guided to the top surface side of the wafer 10a (etching solution 220 side). Etching progresses as the semiconductor material is oxidized by the holes and an oxide is dissolved in the etching solution. In an example where the wafer 10a is composed of GaN, etching progresses in such a manner that GaN is decomposed into gallium (Ga) and nitrogen (N) by the holes, gallium is oxidized by oxygen contained in the etching solution 220 to generate gallium oxide, and gallium oxide is dissolved in an acidic or alkaline etching solution 220. Electrons generated in pairs with holes are guided to the bottom surface side of the wafer 10a.

See FIG. 3B. By etching the outer portion of the mask 160 of the wafer 10a (in planer view) to form the gate recess 15, the gate protrusion 16 is formed under the mask 160 (the gate protrusion 16 remains under the mask 160.) As the etching of the bottom surface of the gate recess 15 progresses (as the gate recess 15 becomes deeper), the etching of the side surface of the gate protrusion 16, which is the side surface of the gate recess 15, also progresses. That is, the etching of the mutually opposing side surfaces 16a and 16b of the gate protrusion 16 progresses, and the width of the gate protrusion 16 becomes narrower.

It is preferable that the light 231 has a light component that is obliquely incident on the top surface of the wafer 10a so that the side surface 16a and the side surface 16b of the gate protrusion 16 are easily irradiated with the light 231. Further, by etching the side surfaces 16a and 16b, the width of the gate protrusion 16 becomes narrower than the width of the mask 160. Therefore, it is preferable to form the mask 160 with a width slightly wider than a final width W of the gate protrusion 16 desired to be obtained.

The holes move by diffusing a non-depleted region of the wafer 10a. At the stage where the width of the gate protrusion 16 is sufficiently wide, specifically, in the gate protrusion 16, at the stage where the non-depleted region remains between the depletion layer 10D formed on the side surface 16a and the depletion layer 10D formed on the side surface 16b, etching of the side surfaces 16a and 16b progresses as the holes move through the non-depleted region.

See FIG. 3C. Since the holes can no longer move at a stage when the width of the gate protrusion 16 is narrowed to a width W which is a width corresponding to the depletion layer 10D formed over an entire width of the gate protrusion 16, the etching of the side surfaces 16a and 16b is automatically stopped.

After the width of the gate protrusion 16 reaches the width W and the etching of the side surfaces 16a and 16b stops, and when the etching progresses until the depth of the gate recess 15 reaches a predetermined depth, the PEC etching is completed by stopping the irradiation of the light 231.

The FET 100 in this example is a FinFET, and the mask 160 includes a linear portion (in planer view). In the step of the PEC etching, the gate protrusion 16 is formed, including a linear portion having a width W of 200 nm or more and 2000 nm or less at the narrowest portion (in planer view).

As described above, the step of forming the gate protrusion 16 by PEC etching (method for manufacturing the semiconductor member 10 according to the embodiment) includes the step of preparing the processing target 150, and the step of performing PEC etching to the wafer 10a by immersing the processing target 150 in the etching solution 220 and irradiating the wafer 10a with light 231 from the top surface side.

In the step of PEC etching the wafer 10a, by etching the outer portion of the mask 160 of the wafer 10a, the gate protrusion 16 is formed under the mask 160, and by etching the side surfaces 16a and 16b until the entire width between the mutually opposing side surfaces 16a and 16b of the gate protrusion 16 is depleted, the etching of the side surfaces 16a and 16b is automatically stopped.

The width W of the gate protrusion 16 formed according to the embodiment is determined by the width of the depletion layer 10D. As will be described below, the width of the depletion layer 10D is determined by the carrier concentration of the semiconductor member 10, more specifically, the carrier concentration of the portion where the gate protrusion 16 is formed (drift layer 12 in this example), and the pH of the etching solution 220. Accordingly, even when there is an error in the size of the mask 160, the width W of the gate protrusion 16 can be precisely controlled by the carrier concentration and the pH of the etching solution 220.

In a FinFET type power device, a threshold voltage for switching on/off is determined by the width W of the gate protrusion 16 which is the gate portion. Therefore, it is preferable to precisely control the width W. The preferable width W is estimated as follows.

An example of a Schottky gate electrode structure in which the semiconductor member 10 is composed of GaN and the gate electrode 20 is composed of gold (Au) will be shown for example. The depletion layer width Wp in a Schottky junction is represented by the following formula 1.

$$[ Formula 1 ]$$

$${W}_{D} = \sqrt{\frac{2 {ε}_{r} {ε}_{0} ( {Φ}_{b i} - V )}{qn}} \qquad ( 1 )$$

Wherein εᵣ is a relative dielectric constant 9.5 of GaN, ε₀ is a dielectric constant 8.85×10⁻¹²F/m of vacuum, Φ_{bi} is a built-in potential, V is an applied voltage, q is an elementary charge 1.60×10⁻¹⁹ C, and n is a carrier concentration of GaN.

The built-in potential Φ_{bi} is represented by the following formula 2.

$$[ Formula 2 ]$$

$${Φ}_{b i} = {Φ}_{B} - kt \cdot log ( {N}_{C} / n ) \qquad ( 2 )$$

wherein Φ_{B} is a Schottky barrier 1 eV in the contact between GaN and Au, k is a Boltzmann constant 1.38×10⁻²³ J/K, t is an absolute temperature 300 K, and N_{C} is an effective state density 2.59×10²⁴/m³ of a GaN conduction band.

Since the width W of the gate protrusion 16 is formed to be twice the depletion layer width W_{D}, the entire width of the gate protrusion 16 is depleted when the voltage V is applied to the gate electrode 20. FIG.

6A is a table showing the dependence of a value twice the depletion layer width W_{D} (that is, a value of the width W of the fully depleted gate protrusion 16) at each carrier concentration n, on the applied voltage V when the Schottky barrier Φ_{B} is 1 eV.

The carrier concentration n is varied to 5×10¹⁵/cm³, 8×10¹⁵/cm³, 1×10¹⁶/cm³, and 2×10¹⁶/cm³. The applied voltage V is varied from +0.2V to −0.35V in steps of 0.05V (50 mV). The width W is shown in unit of nm. A GaN power device with a withstand voltage of 2.5 kV when the carrier concentration n is 5×10¹⁵/cm³, and a GaN power device with a withstand voltage of 1.5 kV when the carrier concentration n is 1×10¹⁶/cm³, can be realized.

Regarding a specific carrier concentration n, when the width W of the gate protrusion 16 is the value shown in this table, the FinFET reaches exactly the OFF state at the applied voltage V. That is, this applied voltage V is a threshold value. For example, when the carrier concentration n is 1×10¹⁶/cm³, the width W is 600 nm, and the applied voltage V is 0, the entire width W is depleted and the FinFET is set in the OFF state.

A design in which the FinFET is set exactly in the OFF state (pinch-off) when the applied voltage V is 0, will be considered. FIG. 6B is a table showing the allowable error of the width W of the gate protrusion 16 when the allowable error of the threshold value is ±50 mV and ±100 m V. When the allowable error of the threshold voltage is ±50-100 mV, the allowable error of the width W of the gate protrusion 16 is ±10-50 nm. It is very difficult to suppress the allowable error of the width W of the gate protrusion 16 to such a low level using conventional lithography.

In the embodiment, the gate protrusion 16 is formed by PEC etching, as described above. A barrier height of the semiconductor member 10 in contact with the etching solution 220 is controlled by pH of the etching solution 220. Accordingly, the depletion layer width W_{D} in PEC etching, that is, the width W of the gate protrusion 16 to be formed, is controlled by the pH of the etching solution 220.

More specifically, by adjusting the pH of the etching solution

220 so as to be equivalent to the Schottky barrier Φ_{B} in a Schottky electrode structure to be produced, the depletion layer width W_{D} in PEC etching can be adjusted to be equal to the depletion layer width W_{D} in the case of the applied voltage of V=0 in the Schottky electrode structure. In this way, it is possible to form the gate protrusion 16 having the width W so as to be exactly set in the OFF state at the applied voltage V of 0 when the Schottky electrode structure is formed.

As described above, the width W of the gate protrusion 16 according to the embodiment can be precisely controlled by the carrier concentration n and the pH of the etching solution 220. With a current growth technique, wafer in-plane variation in the carrier concentration n can be suppressed to about ±2% on average. For example, when the carrier concentration n is 1×10¹⁶/cm³ ±2%, the wafer in-plane allowable error in the width W is ±6 nm and can be ±10 nm or less.

For example, in a comparative embodiment in which the gate protrusion 16 is formed using a combination of ultraviolet lithography using a stepper and dry etching, the yield of the element remains at about 50%. In contrast, in the gate protrusion 16 formed by the PEC etching of the embodiment as described above, the allowable error in the width W can be suppressed to ±10 nm or less. Therefore, the yield can be improved.

In the comparative embodiment using dry etching, there is a concern that damage to a semiconductor crystal may occur due to dry etching.

In contrast, in the embodiment, since the gate protrusion 16 is formed by PEC etching, which is wet etching, damage to the semiconductor crystal is suppressed. Further, in the embodiment, the width W can be determined by automatically stopping etching in a width direction of the gate protrusion 16. Further, in the embodiment, since the fully depleted gate protrusion 16 can be formed, the obtained FET 100 can be of a normally-off type.

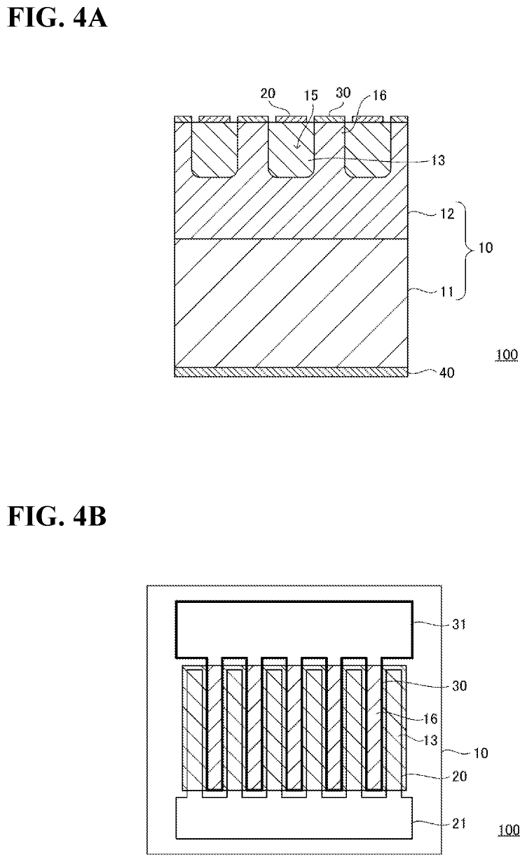

Next, a FET 100 according to a modified example of the above-described embodiment will be described. FIGS. 4A and 4B are a cross-sectional view and a top view, respectively, schematically illustrating the FET 100 according to a first modified example.

In the embodiment described above, the FET 100 having a Schottky type (or MOS type) gate electrode structure is shown for example. The gate electrode structure is not limited thereto. As a first modified example, an FET 100 having a pn-type gate electrode structure will be shown for example.

In the first modified example, the gate recess 15 is filled with a semiconductor layer 13 (hatched portion upward to the left) of a conductivity type (that is, p-type) opposite to that of the drift layer 12. The gate electrode 20 is formed on the semiconductor layer 13. The gate voltage is applied via the semiconductor layer 13 to the pn junction formed by the semiconductor layer 13 and the gate protrusion 16.

Regarding the method for manufacturing the FET 100 according to the first modification, the steps up to the step of forming the gate protrusion 16 are the same as in the above-described embodiment. After forming the gate protrusion 16, the semiconductor layer 13 is formed, for example, by regrowth. If necessary, polishing may be performed to flatten the top surface of the semiconductor member 10 on which the semiconductor layer 13 has been grown. Thereafter, the FET 100 according to the first modified example is manufactured by forming the gate electrode 20, the source electrode 30, the drain electrode 40, and other member such as an insulating film on the semiconductor member 10.

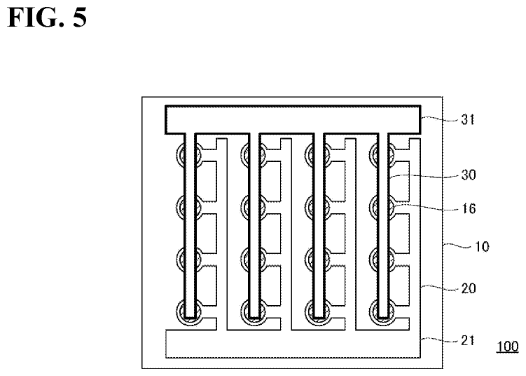

FIG. 5 is a top view schematically illustrating the FET 100 according to the second modified example. In the above-described embodiment, the FET 100 having a fin-shaped (linear) gate protrusion 16 was shown for example. The shape of the gate protrusion 16 is not limited thereto. As a second modified example, the FET 100 (nanorod transistor) having a rod-shaped (island-shaped) gate protrusion 16 is shown for example. In the nanorod transistor, the gate electrode 20 is formed to surround an entire circumference of the gate protrusion 16 (in planer view).

Regarding the method for manufacturing the FET 100 according to the second modified example, the step of forming the gate protrusion 16 is different from the above-described embodiment. In this example, the mask 160 includes an island-shaped portion (in planer view). In the PEC etching step, the gate protrusion 16 is formed, including an island-shaped portion having a width W of 200 nm or more and 2000 nm or less at the narrowest portion (in planer view). After forming the gate protrusion 16, by forming the gate electrode 20, the source electrode 30, the drain electrode 40, and other member such as an insulating film on the semiconductor member 10, the FET 100 according to the second modified example is manufactured.

Regarding the FET 100 according to the first modified example and the second modified example, similarly to the embodiments described above, advantages are the same, such as the ability to precisely control the width W by forming the fully depleted gate protrusion 16 by PEC etching.

### <Preferable Aspects of the Present Invention>

Hereinafter, preferable aspects of the present invention will be supplementarily described.

### (Supplementary Description 1)

A method for manufacturing a semiconductor member, the method including:
preparing a processing target comprising a wafer composed of a conductive semiconductor and a mask disposed on a top surface of the wafer; and
photoelectrochemically etching the wafer by immersing the processing target in an etching solution and irradiating light from a top surface side of the wafer,
wherein in the photoelectrochemical etching of the wafer,
an outer portion of the mask of the wafer is etched to form a protrusion under the mask, and
a first side surface and a second side surface are etched until an entire width between the mutually opposing first side surface and second side surface of the protrusion is depleted, to automatically stop the etching of the first side surface and the second side surface.

### (Supplementary Description 2)

The method for manufacturing a semiconductor member according to supplementary description 1,
wherein the mask includes a linear portion, and
in the photoelectrochemical etching the wafer, the protrusion including the linear portion having a narrowest width of 200 nm or more and 2000 nm or less is formed.

(Supplementary description 3)

The method for manufacturing a semiconductor member according to supplementary description 1,
wherein the mask includes an island-shaped portion, and
in the photoelectrochemical etching of the wafer, the protrusion including the island-shaped portion having a width of 200 nm or more and 2000 nm or less at a narrowest portion is formed.

### (Supplementary Description 4)

The method for manufacturing a semiconductor member according to any one of supplementary descriptions 1 to 3, the method further including:
forming a gate electrode that applies a gate voltage to a side surface of the protrusion, a source electrode disposed on one side of the protrusion in a vertical direction, and a drain electrode disposed on the other side of the protrusion in the vertical direction.

What is claimed is:

1. A method for manufacturing a semiconductor member, the method comprising:
preparing a processing target comprising a wafer composed of a conductive semiconductor and a mask disposed on a top surface of the wafer; and
photoelectrochemically etching the wafer by immersing the processing target in an etching solution and irradiating light from a top surface side of the wafer,
wherein in the photoelectrochemical etching of the wafer,
an outer portion of the mask of the wafer is etched to form a protrusion under the mask, and
a first side surface and a second side surface are etched until an entire width between the mutually opposing first side surface and second side surface of the protrusion is depleted, to automatically stop the etching of the first side surface and the second side surface.

2. The method for manufacturing a semiconductor member according to claim 1,
wherein the mask includes a linear portion, and
in the photoelectrochemical etching of the wafer, the protrusion including the linear portion having a width of 200 nm or more and 2000 nm or less at a narrowest portion is formed.

3. The method for manufacturing a semiconductor member according to claim 1,
wherein the mask includes an island-shaped portion, and
in the photoelectrochemical etching of the wafer, the protrusion including the island-like portion having a width of 200 nm or more and 2000 nm or less at a narrowest portion is formed.

4. The method for manufacturing a semiconductor member according to claim 1, the method further comprising:
forming a gate electrode that applies a gate voltage to a side surface of the protrusion, a source electrode disposed on one side of the protrusion in a vertical direction, and a drain electrode disposed on the other side of the protrusion in the vertical direction.
